(19) United States
(12) Patent Application Publication
(10) Pub. No.: US 2002/0053715 A1
(43) Pub. Date: May 9, 2002

(54) Trench isolation structure having a curvilinear interface at upper corners of the trench isolation region, and method of manufacturing the same

(76) Inventors: Min Kim, Yongin-city (KR); Sun-Hu Park, Yongin-city (KR)

Correspondence Address: JONES VOLENTINE, P.L.L.C., Suite 150, 12200 Sunrise Valley Drive, Reston, VA, 20191, US

(21) Appl. No.: 09/986,247

(22) Filed: Nov. 8, 2001

(30) Foreign Application Priority Data
Nov. 9, 2000 (KR) 2000-66433

(51) Int. Cl. H01L 29/00

(52) U.S. Cl. 257/524

(57) ABSTRACT

The interface between a trench isolation layer and a semiconductor substrate at the uppermost part of the trench isolation region has a curvilinear sectional profile to prevent an electric field from concentrating at the upper corners of the substrate where the active regions are formed. A pad oxide layer and a hard mask layer are sequentially formed on the semiconductor substrate, and are then patterned using photolithography to form a hard mask pattern and a pad oxide pattern. Subsequently, a thermal oxide layer is formed on the substrate, either directly thereon or in a shallow trench formed therein. The thermal oxide layer and the semiconductor substrate are then etched using the hard mask pattern as a mask to form a deep trench and yet leave an outer peripheral portion of the thermal oxide layer at the upper part of the trench isolation region. A buffer layer is formed over the entire upper stepped surface of the resulting structure and then the deep trench is filled with an oxide layer. The resulting structure is planarized and the hard mask pattern is removed to thereby complete the formation of the trench isolation layer.

### BACKGROUND OF THE INVENTION

1. Field of the Invention

The present invention relates to a semiconductor memory device and to the manufacturing of such a device. More particularly, the present invention relates to trench isolation structure of a semiconductor device and to a method of manufacturing the same.

2. Description of the Related Art

The active regions of a semiconductor device traditionally have been electrically isolated by the local oxidation of silicon (LOCOS). Most recently, shallow tench isolation (STI) has been adopted in highly integrated semiconductor memory devices. In STI technology, a narrow trench in a silicon substrate is filled with an insulating material to electrically isolate the active regions.

FIGS. 1-5 show the fabrication steps in the conventional STI process of manufacturing a trench isolation layer. Referring to FIG. 1, a pad oxide layer and a hard mask layer formed of a silicon nitride are sequentially deposited over a semiconductor substrate 14. The semiconductor substrate 14 has a silicon-on-insulator structure in which a silicon substrate 10, a buried oxide layer 11 and a monocrystalline silicon layer 12 are disposed one atop the other. The hard mask layer and the pad oxide layer are sequentially etched using conventional photolithography to form a pad oxide pattern 16 and a hard mask pattern 18, and to expose a portion of the semiconductor substrate 14 at which an isolation layer will be formed.

Referring to FIG. 2, the exposed portion of the semiconductor substrate 14 is anisotropically etched to form a trench 20 in the portion of the substrate 14 where the isolation layer will be formed.

Referring to FIG. 3, an inner wall oxide layer 22 having a thickness of about 100 Å is formed along the inner walls of the substrate that define the trench 20. The inner wall oxide layer 22 is for compensating for damage to the semiconductor substrate 14 suffered during the anisotropic etching of the semiconductor substrate 14. Next, an oxide layer 24 such as a high density plasma (HDP) oxide layer or an undoped silicate glass (USG) layer is formed over the structure to “bury” the trench 20. Then, as shown in FIG. 4, the resulting structure is planarized by chemical mechanical polishing (CMP). In the figure, reference characters 18a and 24a designate the hard mask pattern and oxide layer after the planarization process, respectively.

Referring to FIG. 5, the pad oxide pattern 16a and the hard mask pattern 18a are removed by wet etching to complete the formation of the trench isolation layer.

However, in this conventional method of manufacturing a trench isolation layer, the oxide layer buried in the trench expands due to mechanical stress and due to thermal stress generated during a subsequent thermal process such as gate oxide layer formation. This, in turn, causes silicon dislocations in the semiconductor substrate. The silicon dislocations create a path along which electrons flow, i.e., are a cause of leakage current. Furthermore, the electric field is concentrated at the interface between the semiconductor substrate and the isolation layer at the upper corners of the substrate because the upper corners have a very steep profile. This concentration of the electric field causes breakdown.

### SUMMARY OF THE INVENTION

It is therefore an object of the present invention to provide trench isolation structure of a semiconductor device in which the electric field will not concentrate at the upper corners of the substrate where the upper surface of the substrate and the inner walls of the substrate that define the trench meet.

The object of the present invention is achieved by trench isolation structure wherein the interface between the semiconductor substrate and the trench isolation layer, at upper corners of the substrate where the trench begins, has a rounded, i.e., curvilinear, vertical sectional profile. The trench isolation layer may include a first oxide layer buried in a trench region of the semiconductor substrate, a buffer layer surrounding the first oxide layer, and a thermal oxide layer that contact the buffer layer at the upper corners of the substrate. Thus, the interface between the thermal oxide layer and the semiconductor substrate is rounded. The thermal oxide layer may be grown in such a way that the vertical sectional profile of the interface between the thermal oxide layer and the semiconductor substrate is in the shape of a bird's beak.

The object of the present invention is similarly achieved by a method of fabricating trench isolation structure wherein a thermal oxide layer is grown as part of the trench isolation layer to create an interface with the semiconductor substrate that has a curvilinear vertical sectional profile at upper corners of the substrate where the trench begins. According to the method, a pad oxide layer and a hard mask layer are sequentially formed on a semiconductor substrate, and are then patterned using photolithography to form a hard mask pattern and a pad oxide pattern. Next, a portion of the semiconductor substrate is etched using the hard mask pattern as a mask to thereby form a shallow trench. Then the thermal oxide layer is formed along inner walls of the substrate that define the shallow trench. Subsequently, the thermal oxide layer and the semiconductor substrate are etched using the hard mask pattern as a mask to form a deep trench. A buffer layer is formed over the entire upper stepped surface of the resulting structure and then the deep trench is filled with a first oxide layer. The resulting structure is planarized and the hard mask pattern is removed to thereby complete the formation of the trench isolation layer.

When the semiconductor substrate has a silicon-on-insulator (SOI) structure that includes a silicon substrate, a buried oxide layer disposed on the silicon substrate, and a monocrystalline silicon layer disposed on the buried oxide layer, the shallow trench terminates within the monocrystalline silicon layer. On the other hand, the deep trench terminates at the interface between the buried oxide layer and the silicon substrate or at the interface between the buried oxide layer and the monocrystalline silicon layer.

In an alternative form of the method, the thermal oxide layer is grown on the upper surface of the substrate without first forming a shallow trench. In this case, the thermal oxide layer and the semiconductor substrate are etched using the hard mask pattern as a mask to form the deep trench. Then, the buffer layer and first oxide layer are formed in the deep trench, the resulting structure is planarized, and the hard mask pattern is removed to complete the formation of the trench isolation layer. The thermal oxide layer grown and etched in this way produces the interface having a vertical sectional profile in the shape of a bird's beak.

A spacer may be provided along the sidewalls of the hard mask pattern and the pad oxide pattern. In this case, the shallow trench and/or the deep trench may be formed using the hard mask pattern and the spacer as a mask.

According to the present invention, an electric field will not concentrate along the interface between the insulating structure of the trench isolation layer and the active regions of the semiconductor substrate, at the upper corners of the substrate where the trench begins, because the profile of the interface is curvilinear. Hence, the present invention prevents breakdown from occurring at the interface between the substrate and the trench isolation layer.

Another object of the present invention is to provide trench isolation structure and a method of manufacturing the same, wherein silicon dislocations do not occur in the substrate, whereby leakage current is suppressed.

To this end, a liner is interposed between the buffer layer and the first oxide layer to absorb stress that would otherwise be exerted on the first oxide layer. The liner may be a layer of silicon nitride or boron nitride. Still further, a second oxide layer may, in turn, be interposed between the liner and the first oxide layer.

### BRIEF DESCRIPTION OF THE DRAWINGS

The above and other objects, features and advantages of the present invention will become more apparent by referring to the following detailed description of the preferred embodiments thereof made with reference to the attached drawings, of which:

FIGS. 1-5 are respective cross-sectional views of a semiconductor substrate and show the steps in manufacturing a trench isolation layer according to the prior art;

FIGS. 6 and 7 are cross-sectional views of respective embodiments of trench isolation layers according to the present invention;

FIGS. 8-14 are respective cross-sectional views of a semiconductor substrate and show the steps in an embodiment of a method of manufacturing a trench isolation layer according to the present invention; and

FIGS. 15 and 16 are respective cross-sectional views of a semiconductor substrate and show key steps in another embodiment of a method of manufacturing a trench isolation layer according to the present invention.

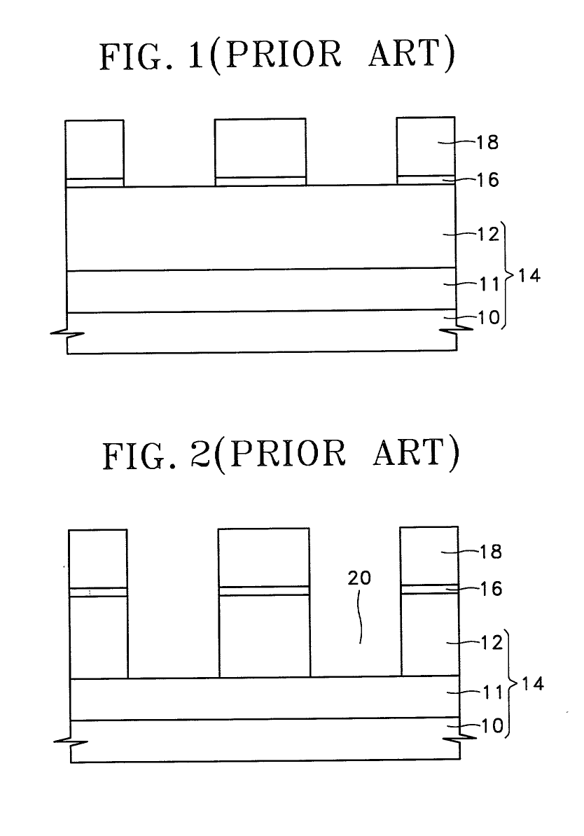

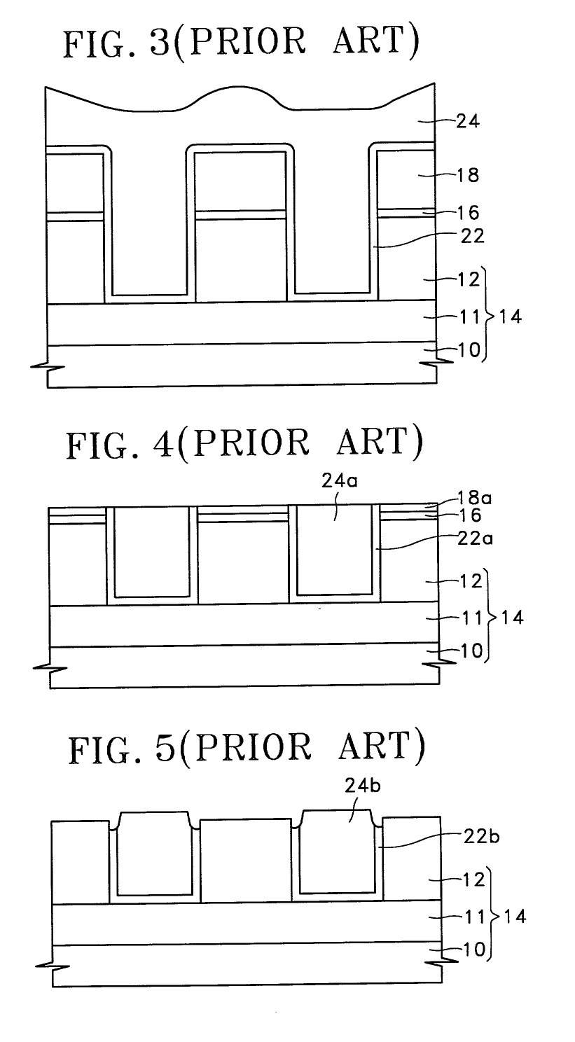

### DETAILED DESCRIPTION OF THE PREFERRED EMBODIMENTS

The present invention will now be described more fully with reference to the accompanying drawings. In the drawings, the shapes of elements are exaggerated for the sake of clarity. Furthermore, when a layer is referred to as being “on” another layer or substrate, such a description means that the layer can be directly on the other layer or substrate, or intervening layers may be interposed therebetween

### EMBODIMENT 1

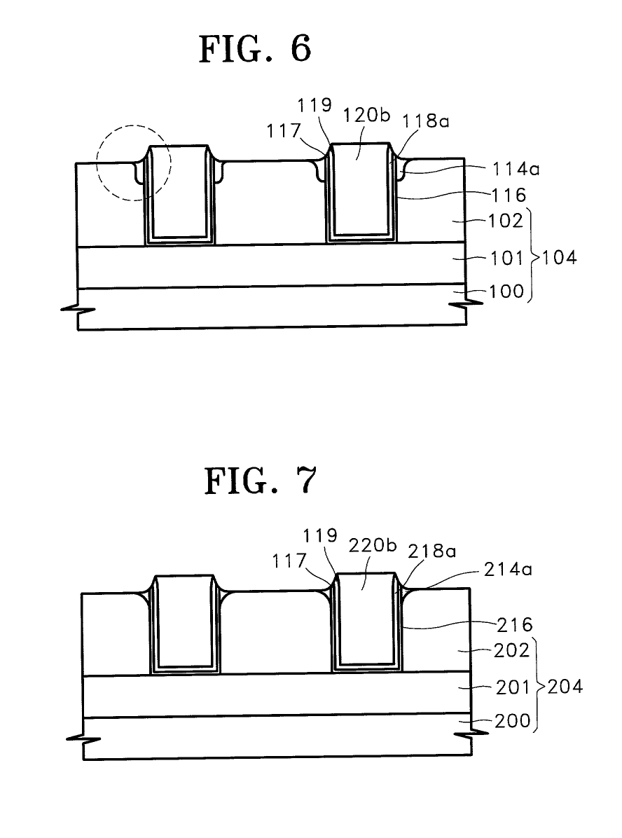

FIG. 6 shows a first embodiment of trench isolation structure in which a trench 116 extends into a semiconductor substrate 104 from an upper surface of the substrate, and a trench isolation layer occupies the trench to electrically isolate active regions. In this embodiment, the trench isolation layer comprises a first oxide layer 120b, a buffer layer 118a, and a thermal oxide layer 114a. The first oxide layer is buried in the trench 116 of the semiconductor substrate 104 as surrounded by the buffer layer 118a. The thermal oxide layer 114a contacts the buffer layer 118a at the upper corners of the substrate 104 where the upper surface of the substrate 104 and inner walls of the substrate 104 that define the trench 116 meet. Thus, the trench isolation layer and the semiconductor substrate contact each other at the upper corners of the substrate 104. This interface between the trench isolation layer and the semiconductor substrate has a rounded vertical sectional profile. More specifically, the interface between the thermal oxide layer 114a and the semiconductor substrate 104 has a rounded, i.e., curvilinear, vertical sectional profile.

The semiconductor substrate 104 has a silicon-on-insulator (SOI) structure in which a silicon substrate 100, a buried oxide layer 101, and a monocrystalline silicon layer 102 are disposed one atop the other. The trench 116 may extend down to the interface between the monocrystalline silicon layer 102 and the buried oxide layer 101 or to the interface between the buried oxide layer 101 and the silicon substrate 100. The buffer layer 118a is preferably a high temperature oxide (HTO) layer, a middle temperature oxide (MTO) layer or a plasma enhanced (PE)-oxide layer. The first oxide layer 120b is preferably an undoped silicate glass (USG) layer or a high density plasma (HDP) oxide layer.

A liner 117 may be interposed between the buffer layer 118a and the first oxide layer 120b. The liner 117 is preferably a silicon nitride layer or a boron nitride layer. The liner 117 serves to absorb stresses of the first oxide layer 120b buried in the trench 116 and prevent oxygen from penetrating into the buffer layer 118a, thereby inhibiting the formation of silicon dislocations which are the cause of leakage current. A second oxide layer 119 may be interposed between the liner 117 and the first oxide layer 120b. The second oxide layer 119 is preferably an HTO layer, an MTO layer or a PE-oxide layer.

### EMBODIMENT 2

FIG. 7 shows another embodiment of trench isolation structure according to the present invention. In this embodiment, a first oxide layer 220b is buried in a trench 216 of a semiconductor substrate 204 as surrounded by a buffer layer 218a. A thermal oxide layer 214a contacts the buffer layer 218a at the upper corners of the substrate 204 where the upper surface of the substrate 204 and inner walls of the substrate 204 that define the trench 216 meet. The interface between the thermal oxide layer 214a and the semiconductor substrate 204 has a rounded, i.e., curvilinear, vertical sectional profile in the shape of a bird's beak.

The semiconductor substrate 204 has a silicon-on-insulator structure in which a silicon substrate 200, a buried oxide layer 201, and a monocrystalline silicon layer 202 are disposed one atop the other. The trench 216 may extend down to the interface between the monocrystalline silicon layer 202 and the buried oxide layer 201 or to the interface between the buried oxide layer 201 and the silicon substrate 200. The buffer layer 218a is preferably an HTO layer, an MTO layer or a PE-oxide layer. The first oxide layer 220b is preferably a USG layer or an HDP oxide layer.

A liner 217 may be interposed between the buffer layer 218a and the first oxide layer 220b. The liner 217 is preferably a silicon nitride layer or a boron nitride layer. The liner 217 serves to absorb stress otherwise exerted on the oxide layers buried in the trench 216 and to prevent oxygen from penetrating into the buffer layer 218a, thereby inhibiting the formation of silicon dislocations which are the cause of leakage current. A second oxide layer 219 may be interposed between the liner 217 and the first oxide layer 220b. The second oxide layer 219 is preferably an HTO layer, an MTO layer or a PE-oxide layer.

Methods of manufacturing the tench isolation layers according to the present invention will now be described.

### EMBODIMENT 1

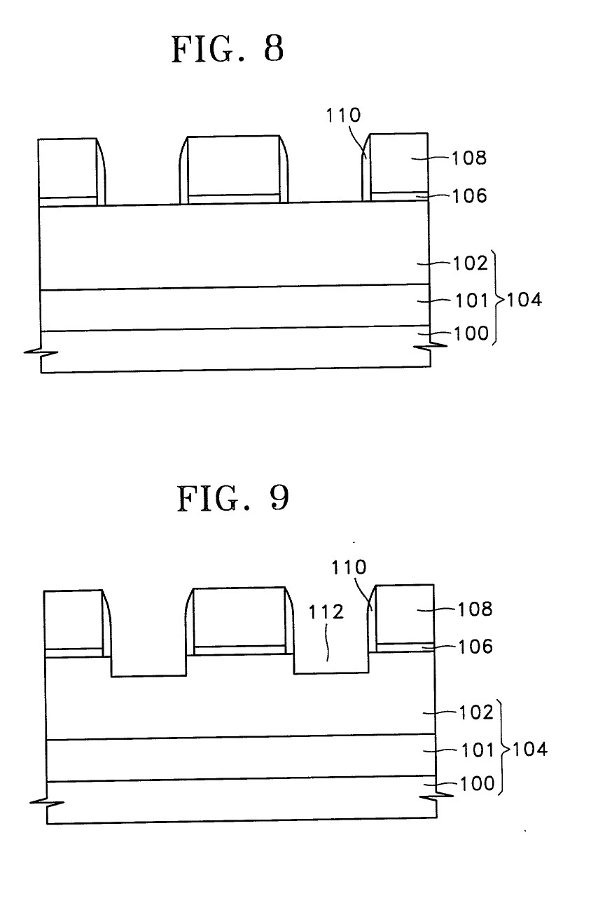

FIGS. 8-14 show steps in one method of manufacturing a trench isolation layer according to the present invention. Referring to FIG. 8, a pad oxide layer and a hard mask layer are sequentially deposited over a semiconductor substrate 104. The semiconductor substrate 104 has a silicon-on-insulator structure in which a silicon substrate 100, a buried oxide layer 101, and a monocrystalline silicon layer 102 are sequentially disposed one atop the other. The pad oxide layer may be a silicon oxide layer having a thickness of about 50-300 Å, and preferably, of about 100 Å. The hard mask layer preferably has a thickness of about 1,000-3,000 Å. The hard mask layer may consist of a silicon nitride layer, a composite layer of silicon nitride and an oxide sequentially disposed one atop the other, or a composite layer in which either an anti-reflective material or an anti-reflective coating is incorporated.

Subsequently, the hard mask layer and the pad oxide layer are patterned using a photolithography process, known per se, to form a hard mask pattern 108 and a pad oxide pattern 106.

An oxide layer such as an HTO oxide layer, a MTO layer or a PE-oxide layer is formed over the resulting structure. Then the resulting structure is anisotropically etched to form a spacer 110 along the sidewall of the hard mask pattern 108 and the pad oxide pattern 106. However, the spacer 110 can be formed at later stages of the process.

Referring now to FIG. 9, using the hard mask pattern 108 and the spacer 110 as a mask, a shallow trench 112 is formed in a portion of the semiconductor substrate 104. The shall trench 112 is preferably formed within the monocrystalline silicon layer 102 itself, i.e. does not extend down to the buried oxide layer.

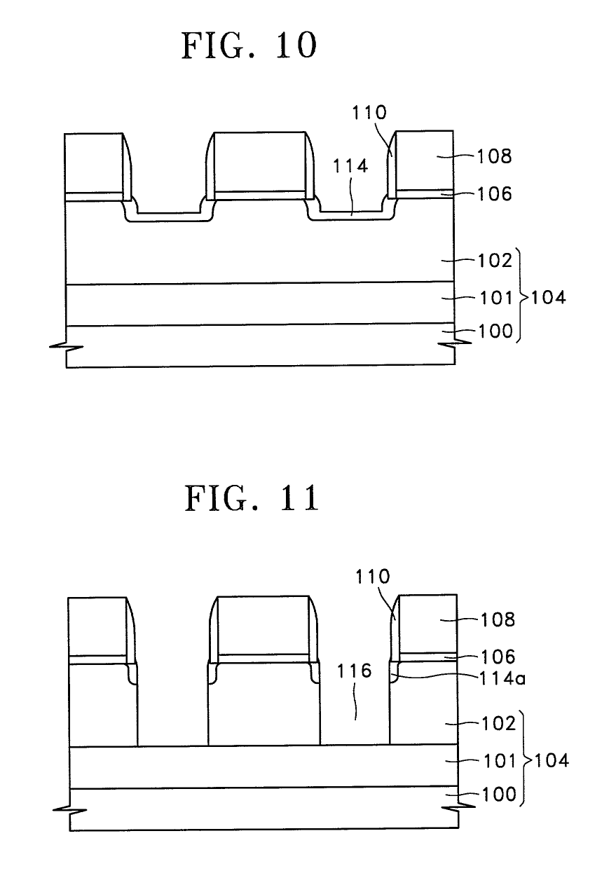

Referring to FIG. 10, a thermal oxide layer 114 having a predetermined thickness of about 20-500 Å, and preferably of about 110 Å, is formed along the inner walls of the substrate 104 that define the shallow trench 112. For example, the semiconductor substrate 104, in which the shallow trench 112 has been formed, is subjected to thermal oxidation. In this process, silicon reacts with oxygen such that an oxide grows from the surface of the semiconductor substrate 104 to form the thermal oxide layer 114. The oxide grows to a location beneath the spacer 110/hard mask pattern 108. In this case, the interface between the thermal oxide layer 114 and the semiconductor substrate 104 is constituted by rounded corners at the location where the shallow trench 112 extends into the substrate 104 from the upper surface thereof.

Referring to FIG. 11, the thermal oxide layer 114 and the semiconductor substrate 104 are etched using the hard mask pattern 108 and the spacer 110 as a mask, to thereby form a deep trench 116. The outer peripheral portion of the thermal oxide layer 114 remains as protected by the spacer 110/hard mask pattern 108. The deep trench 116 may terminate at the interface between the monocrystalline silicon layer 102 and the buried oxide layer 101. Alternatively, the deep trench 116 may terminate at the interface between the buried oxide layer 101 and the silicon substrate 100.

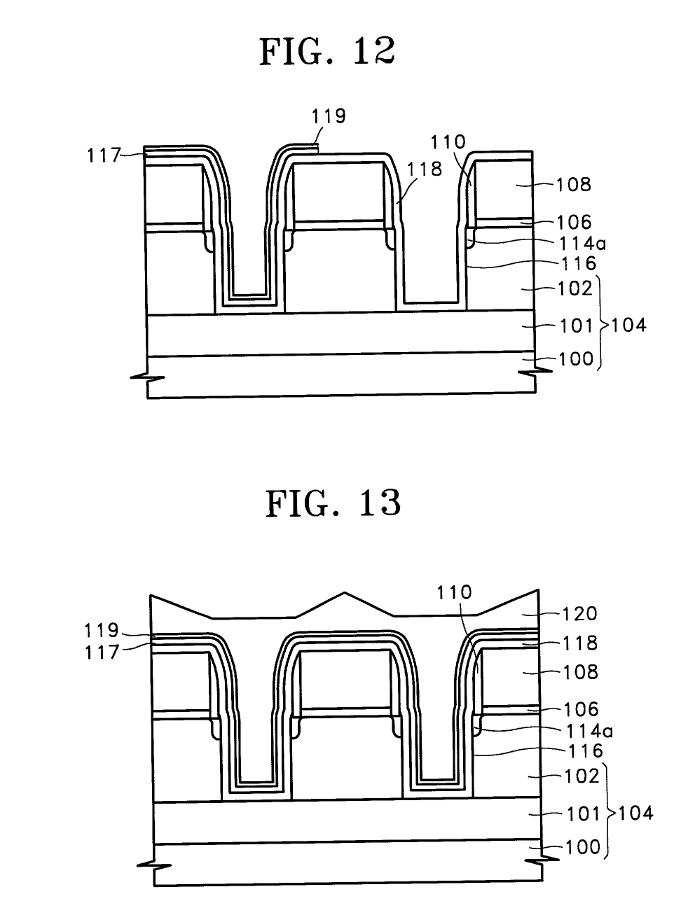

Referring to FIG. 12, a buffer layer 118 is formed over the entire stepped surface of the structure in which the deep trench has been formed. The buffer layer 118 is preferably an oxide layer such as an HTO layer, an MTO layer or a PE-oxide layer. A liner 117 (partially shown for ease in illustration by a chained line) may be formed on the stepped buffer layer 118. The liner is preferably a silicon nitride layer or a boron nitride (BN) layer. A first oxide layer 119 (also partially shown) may be formed on the stepped surface of the resulting structure. The first oxide layer is preferably an HTO layer, an MTO layer, or a PE-oxide layer.

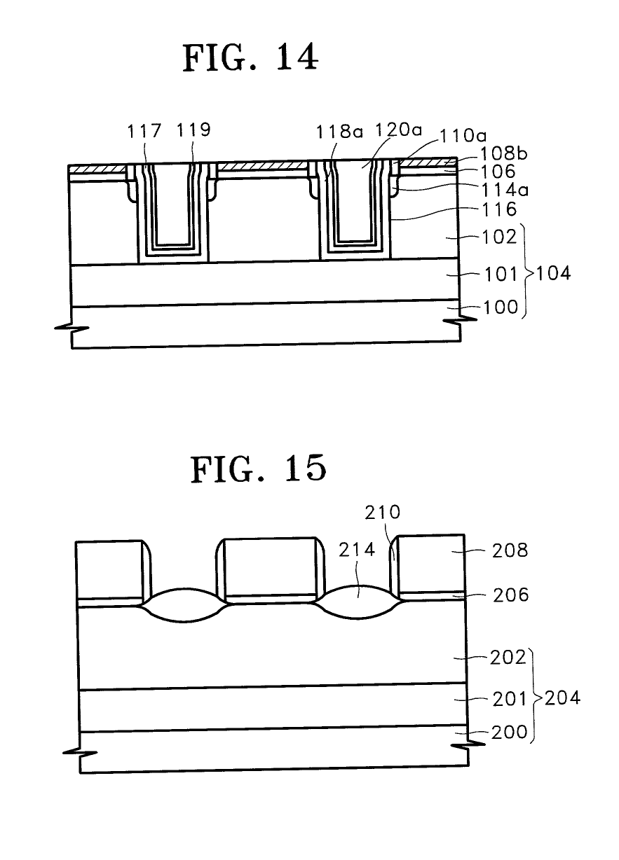

Referring to FIG. 13, a second oxide layer 120 such as a USG layer or an HDP oxide layer is formed over the resulting structure in which the buffer layer 118 has been formed, to “bury” the tench 116. Referring to FIG. 14, the second oxide layer 120 is then planarized by a chemical mechanical polishing (CMP) or etchback process. In the figure, reference numerals 120a, 118a, and 110a designate the second oxide layer, the buffer layer, and the spacer after planarization, respectively. Subsequently, the hard mask pattern 108b is removed by a wet etch process to form a trench isolation layer of the type shown in FIG. 6. The hard mask pattern formed of silicon nitride may be removed using a phosphoric acid (H₃PO₄) solution, for example.

Meanwhile, the oxide layer(s) buried in the trench would tend to expand due to mechanical stress exerted on the oxide layers or created during a subsequent thermal process such as gate oxide layer formation process. Such stress could induce silicon dislocations in the semiconductor substrate 104. The silicon dislocations, in turn, would create a path along which electrons may flow and, therefore, could cause leakage current. The liner serves to absorb the stress that would otherwise be exerted on the oxide layer(s) buried in the trench 116 and to prevent oxygen from penetrating into the buffer layer 118, thereby inhibiting the formation of the silicon dislocations and suppressing leakage current.

### EMBODIMENT 2

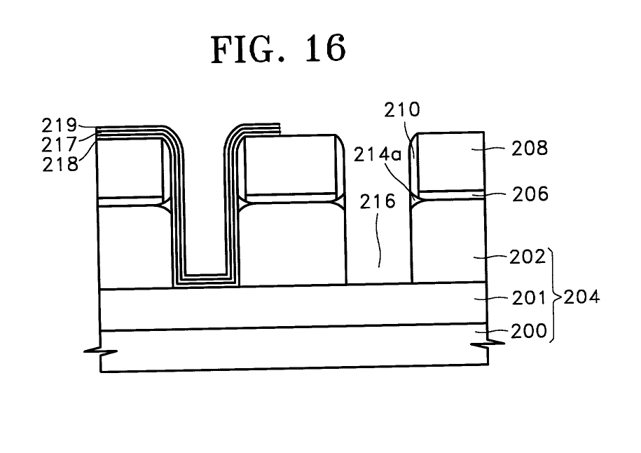

FIGS. 15 and 16 show the key steps in another embodiment of a method of manufacturing a trench isolation layer according to the present invention. Referring to FIG. 15, a pad oxide layer and a hard mask layer are sequentially deposited over a semiconductor substrate 204 and patterned to form a hard mask pattern 208 and a pad oxide pattern 206, and to expose a portion of the upper surface of the semiconductor substrate. Next, a spacer 210 is formed along the sidewalls of the hard mask pattern 208 and a pad oxide pattern 206. As in the first embodiment, the spacer 210 does not need to be formed at this stage of the process.

Subsequently, a thermal oxide layer 212 is formed on the exposed portion of the upper surface of the semiconductor substrate 204. That is, the portion of the semiconductor substrate 204 at which the isolation layer will be formed is subjected to thermal oxidation. Hence, an oxide layer grows from the exposed surface of the semiconductor substrate 204, thereby forming a thermal oxide layer 212 that extends to a location beneath the spacer 210/hard mask pattern 208. In this case, the peripheral portion of the thermal oxide layer 212 has the shape of a bird's beak.

Referring to FIG. 16, the thermal oxide layer 212 and the semiconductor substrate 204 are etched using the hard mask pattern 208 and the spacer 210 as a mask, to thereby form a deep trench 216. The peripheral portion of the thermal oxide layer 212 remains as protected by the spacer 210/hard mask pattern 208. The deep trench 216 is formed down to the interface between the monocrystalline silicon layer 202 and the buried oxide layer 201. Alternatively, the deep trench 216 may be formed down to the interface between the buried oxide layer 201 and the silicon substrate 200. Forming the deep trench 216 in this way leaves the peripheral portion of the thermal oxide layer that has the shape of a bird's beak. That is, the interface between the remaining portion of the thermal oxide layer 212 and the semiconductor substrate 204, at the upper corners of the substrate 204 where the trench 216 begins, has a vertical sectional profile in the shape of a rounded bird's beak as shown in FIG. 16.

Subsequently, a buffer layer is formed, an oxide layer is buried in the deep trench 216, the resulting structure is planarized, and then the hard mask pattern 208 is removed to complete the formation of the trench isolation layer shown in FIG. 7. In addition, before the structure is planarized, a liner 217 and second oxide layer 219 can be formed, as in the first embodiment.

The trench isolation structure and method of manufacturing the same according to the present invention provide an improved profile for the interface between the semiconductor substrate and the isolation layer at the upper corners of the trench isolation region. This profile, which is curvilinear, serves to prevent an electric field from concentrating at the upper corners of the trench isolation region. Furthermore, the present invention also obviates the problem of leakage current associated with silicon dislocations by providing a liner between the buffer layer and the oxide layer buried in the trench.

Finally, although the present invention has been shown and described with reference to the preferred embodiments thereof, it will be understood by those skilled in the art that various changes in form and details may be made thereto without departing from the spirit and scope of the invention as defined by the appended claims.

What is claimed is:

1. Trench isolation structure of a semiconductor device comprising:
a semiconductor substrate having an upper surface, and a trench extending into the substrate from said upper surface such that the substrate has upper corners where said upper surface and inner walls of the substrate that define the trench meet; and a trench isolation layer filling said trench, wherein the trench isolation layer and the semiconductor substrate contact each other at said upper corners along an interface, said interface having a rounded vertical sectional profile.

2. The trench isolation structure of claim 1, wherein said trench isolation layer comprises a first oxide layer buried in said trench, a buffer layer surrounding the first oxide layer, and a thermal oxide layer that contacts said buffer layer and said upper corners of the substrate, wherein said interface having a rounded vertical sectional profile exists between said thermal oxide layer and the semiconductor substrate.

3. The trench isolation structure of claim 2, wherein said rounded vertical sectional profile is in the shape of a bird's beak.

4. The trench isolation structure of claim 2, wherein said semiconductor substrate has a silicon-on-insulator (SOI) structure of respective layers that include a silicon substrate, a buried oxide layer disposed on the silicon substrate, and a monocrystalline silicon layer disposed on the buried oxide layer.

5. The trench isolation layer of claim 4, wherein said trench terminates at an interface between two of the respective layers of said SOI structure.

6. The trench isolation layer of claim 2, wherein said buffer layer is one of a high temperature oxide layer, a middle temperature oxide layer and a plasma enhanced-oxide layer.

7. The trench isolation layer of claim 2, and further comprising a liner interposed between said buffer layer and said first oxide layer.

8. The trench isolation layer of claim 7, wherein said liner is one of a silicon nitride layer and a boron nitride layer.

9. The trench isolation layer of claim 7, and further comprising a second oxide layer interposed between said liner and said first oxide layer.

10. The trench isolation layer of claim 9, wherein said second oxide layer is one of a high temperature oxide layer, a middle temperature oxide layer and a plasma enhanced-oxide layer.

11. A method of manufacturing trench isolation structure of a semiconductor device, the method comprising the steps of:
(a) sequentially forming a pad oxide layer and a hard mask layer on a semiconductor substrate;
(b) patterning the hard mask layer and the pad oxide layer by photolithography to form a hard mask pattern and a pad oxide pattern;
(c) etching a portion of the semiconductor substrate using the hard mask pattern as a mask to thereby form a shallow trench;
(d) forming a thermal oxide layer along inner walls of the semiconductor substrate that define the shallow trench;
(e) etching away portions of the thermal oxide layer and the semiconductor substrate using the hard mask pattern as a mask to extend said shallow trench deeper into the semiconductor substrate and thereby form a deep trench;
(f) forming a buffer layer over the entire upper surface of the structure in which the deep trench has been formed;
(g) filling the deep trench, in which the buffer layer has been formed, with a first oxide layer;
(h) planarizing the resulting structure in which the deep trench has been filled with the first oxide layer; and
(i) removing the hard mask pattern.

12. The method of claim 11, and further comprising the step of forming a spacer along sidewalls of the hard mask pattern and the pad oxide pattern, and wherein step (c) comprises etching a portion of the semiconductor substrate using the hard mask pattern and the spacer as a mask to thereby form the shallow trench, and step (e) comprises etching the thermal oxide layer and the semiconductor substrate using the hard mask pattern and the spacer as a mask to thereby form the deep trench.

13. The method of claim 11, and further comprising the step of forming a liner between the buffer layer and the first oxide layer.

14. The method of claim 12, and further comprising the step of forming a second oxide layer between the liner and the first oxide layer.

15. The method of claim 11, wherein the semiconductor substrate has a silicon-on-insulator (SOI) structure of respective layers that include a silicon substrate, a buried oxide layer, and a monocrystalline silicon layer disposed one atop the other, and wherein step (c) comprises terminating the etching of the semiconductor substrate at a location within the monocrystalline silicon layer in forming the shallow trench.

16. The method of claim 15, wherein step (e) comprises terminating the etching of the semiconductor substrate at an interface between two of the respective layers of the SOI structure in forming the deep trench.

17. A method of manufacturing a trench isolation layer, the method comprising the steps of:
(a) sequentially forming a pad oxide layer and a hard mask layer on an upper surface of a semiconductor substrate;
(b) patterning the hard mask layer and the pad oxide layer using photolithography to form a hard mask pattern and a pad oxide pattern;
(c) forming a thermal oxide layer on a portion of the upper surface of the semiconductor substrate where a trench isolation layer will be formed;
(d) etching away portions of the thermal oxide layer and the semiconductor substrate using the hard mask pattern as a mask to thereby form a deep trench;
(e) forming a buffer layer over the entire upper surface of the resulting structure in which the deep trench has been formed;
(f) filling the deep trench, in which the buffer layer has been formed, with a first oxide layer;
(g) planarizing the resulting structure in which the deep trench has been filled with the first oxide layer; and
(h) removing the hard mask pattern.

18. The method of claim 17, and further comprising the step of forming a spacer along sidewalls of the hard mask pattern and the pad oxide pattern, and wherein step (d) comprises etching the thermal oxide layer and the semiconductor substrate using the hard mask pattern and the spacer as a mask to thereby form the deep trench.

19. The method of claim 17, and further comprising the step of forming a liner between the buffer layer and the first oxide layer.

20. The method of claim 19, and further comprising the step of forming a second oxide layer between the liner and the first oxide layer.

21. The method of claim 17, wherein the semiconductor substrate has a silicon-on-insulator (SOI) structure of respective layers that include a silicon substrate, a buried oxide layer, and a monocrystalline silicon layer disposed one atop the other, and wherein step (d) comprises terminating the etching of the semiconductor substrate at an interface between two of the respective layers of the SOI structure in forming the deep trench.
